(19) United States
(12) Patent Application Publication
(10) Pub. No.: US 2021/0351376 A1
(43) Pub. Date: Nov. 11, 2021

(54) OLED DISPLAY PANEL AND FABRICATION METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventors: Bin Xu, Wuhan (CN); Hongyu Xu, Wuhan (CN)

(21) Appl. No.: 16/320,064

(22) PCT Filed: Sep. 5, 2018
(86) PCT No.: PCT/CN2018/104056

§ 371 Date: Jan. 23, 2019

(30) Foreign Application Priority Data
Aug. 15, 2018 (CN) 201810929077.5

(51) Int. Cl. H01L 51/52; H01L 51/56

(52) U.S. Cl. CPC H01L 51/5253; H01L 51/56

(57) ABSTRACT

An organic light-emitting diode (OLED) display panel and a fabrication method thereof are provided. The OLED display panel includes an OLED substrate and a package portion. The OLED substrate includes an array substrate and an OLED layer disposed on the array substrate. The package portion includes: a first inorganic layer disposed on the OLED substrate and covering the OLED layer; an organic layer disposed on the first inorganic layer; a second inorganic layer disposed on a circumferential periphery of the first inorganic layer; and a third inorganic layer disposed on the organic layer and covering the organic layer and the second inorganic layer.

### FIELD OF INVENTION

The present disclosure relates to a technical field of displays, and more particularly to an organic light-emitting diode (OLED) display panel and a fabrication method thereof.

### BACKGROUND OF INVENTION

Organic light-emitting diodes (OLEDs) have advantages of being self-luminous, having low power consumption, having wide view angles, having rich colors, having fast responses, etc. OLEDs may also be used to prepare flexible displays. Therefore, OLEDs have attracted great interest from research community and industry, and are considered to be promising next-generation technologies.

As illustrated in FIG. 1, currently, OLED screens widely applied to the field of displays usually use a top-emitting device structure. An organic light-emitting device 12 is composed of an anode, an organic layer, and a cathode. The organic layer includes a hole injection layer, a hole transport layer, a light-emitting layer, an electron transport layer, a light-emitting layer, an electron transport, and an electron injection layer.

Because the organic layer and the cathode are very sensitive to water and oxygen, various measures need to be taken when preparing a flexible OLED screen, to encapsulate the organic light-emitting device 12. Currently, thin film encapsulation (TFE) technologies have been successfully applied to flexible OLED screens. Currently, the most common technology used by TFE is alternately depositing polymer organic films and inorganic films on surfaces of flexible OLED devices. As illustrated in FIG. 1, layers 13 and 15 are inorganic layers, FIG. 14 is an organic layer. Inorganic layers may have excellent water and oxygen barrier properties. Polymer organic layers may absorb and disperse stress between layers well, avoiding cracks lowering water and oxygen barrier properties to be formed in dense inorganic layers. In a display region of an OLED display panel 1, TFE may ensure encapsulation properties of the OLED device 12. However, at a periphery region, fabrication processes of the OLED display panel 1 or various other reasons may easily cause water and oxygen to invade, resulting in corrosion of the OLED device 12. Therefore, it is desired to provide an OLED display device to solve the aforementioned problems.

### SUMMARY OF INVENTION

The present disclosure provides an organic light-emitting diode (OLED) display panel and a fabrication method thereof, to solve the problem that in the existing OLED display panel, a circumferential periphery region is less water and oxygen resistant, causing water and oxygen to invade and an OLED layer to corrode.

In order to solve the aforementioned problems, the present disclosure provides the following solutions.

In accordance with an aspect of the present disclosure, an OLED display panel is provided. The OLED display panel includes an OLED substrate and a package portion disposed on the OLED substrate;
wherein the OLED substrate includes an array substrate and an OLED layer disposed on the array substrate;
wherein the package portion includes:
   a first inorganic layer disposed on the OLED substrate and covering the OLED layer;
   an organic layer disposed on the first inorganic layer;
   a second inorganic layer disposed on a circumferential periphery of the first inorganic layer, wherein the second inorganic layer partially covers an upper surface of the organic layer; and
   a third inorganic layer disposed on the organic layer and covering the organic layer and the second inorganic layer.

In accordance with an embodiment of the present disclosure, the second inorganic layer contacts a circumferential periphery of the organic layer.

In accordance with an embodiment of the present disclosure, the second inorganic layer covers a circumferential periphery of the organic layer.

In accordance with an embodiment of the present disclosure, the OLED display panel further includes at least one retaining wall disposed on the array substrate and surrounding the OLED layer.

In accordance with an embodiment of the present disclosure, the first inorganic layer covers the at least one retaining wall, and the second inorganic layer extends from the at least one retaining wall and a boundary of the second inorganic layer does not exceed a boundary of the first inorganic layer.

In accordance with an embodiment of the present disclosure, there is one retaining wall, the first inorganic layer extends from the OLED layer to a first side of the retaining wall away from the OLED layer, the organic layer is blocked by the retaining wall to be within a second side of the retaining wall close to the OLED layer, and the second inorganic layer extends from the retaining wall towards an end of the array substrate and completely covers the retaining wall.

In accordance with an embodiment of the present disclosure, there are at least two retaining walls, the first inorganic layer extends from the OLED layer and covers all of the retaining walls, the second inorganic layer extends from the innermost retaining wall of the retaining walls, and covers the outermost retaining wall of the retaining walls.

In accordance with an embodiment of the present disclosure, the third inorganic layer extends from the OLED layer, and a boundary of the third inorganic layer exceeds the boundary of the first inorganic layer.

In accordance with another aspect of the present disclosure, a method for fabricating an OLED display panel is provided. The method is for preparing any of the OLED display panels of Claims 1-10. The method for fabricating the OLED display panel includes:
a step S10 of forming an OLED layer on an array substrate;
a step S20 of forming a first inorganic layer on and covering the OLED layer;
a step S30 of forming a second inorganic layer on a circumferential periphery of the first inorganic layer;
a step S40 of forming an organic layer over the OLED layer, wherein the organic layer covers a region of the first inorganic layer not covered by the second inorganic layer; and
a step S50 of forming a third inorganic layer over the OLED layer, wherein the third inorganic layer covers the second inorganic layer and the organic layer.

In accordance with an embodiment of the present disclosure, the step S30 includes:
a step S301 of coating a photoresist layer on a surface of the first inorganic layer, and exposing and developing the photoresist layer, to obtain a patterned photoresist layer, wherein an area of an upper surface of the patterned photoresist layer is larger than an area of a lower surface of the patterned photoresist layer, and the lower surface of the patterned photoresist layer contacts the first inorganic layer; and
a step S302 of preparing an inorganic film over the first inorganic layer and using stripping liquid to strip the patterned photoresist layer and an inorganic film to be stripped on the upper surface of the patterned photoresist layer, so that a remaining inorganic film forms the second inorganic layer.

In accordance with an embodiment of the present disclosure, the patterned photoresist layer is located over the OLED layer, and an area of the patterned photoresist layer is larger than an area of the OLED layer.

In accordance with still another aspect of the present disclosure, an OLED display panel is provided. The OLED display panel includes an OLED substrate and a package portion disposed on the OLED substrate;
wherein the OLED substrate includes an array substrate and an OLED layer disposed on the array substrate;
wherein the package portion includes:
   a first inorganic layer disposed on the OLED substrate and covering the OLED layer;
   an organic layer disposed on the first inorganic layer;
   a second inorganic layer disposed on a circumferential periphery of the first inorganic layer; and
   a third inorganic layer disposed on the organic layer and covering the organic layer and the second inorganic layer.

In accordance with an embodiment of the present disclosure, the second inorganic layer contacts a circumferential periphery of the organic layer.

In accordance with an embodiment of the present disclosure, the second inorganic layer covers a circumferential periphery of the organic layer.

In accordance with an embodiment of the present disclosure, the OLED display panel further includes at least one retaining wall disposed on the array substrate and surrounding the OLED layer.

In accordance with an embodiment of the present disclosure, the first inorganic layer covers the at least one retaining wall, and the second inorganic layer extends from the at least one retaining wall and a boundary of the second inorganic layer does not exceed a boundary of the first inorganic layer.

In accordance with an embodiment of the present disclosure, there is one retaining wall, the first inorganic layer extends from the OLED layer to a first side of the retaining wall away from the OLED layer, the organic layer is blocked by the retaining wall to be within a second side of the retaining wall close to the OLED layer, and the second inorganic layer extends from the retaining wall towards an end of the array substrate and completely covers the retaining wall.

In accordance with an embodiment of the present disclosure, there are at least two retaining walls, the first inorganic layer extends from the OLED layer and covers all of the retaining walls, the second inorganic layer extends from the innermost retaining wall of the retaining walls, and covers the outermost retaining wall of the retaining walls.

In accordance with an embodiment of the present disclosure, the third inorganic layer extends from the OLED layer, and a boundary of the third inorganic layer exceeds the boundary of the first inorganic layer.

Advantages of the present disclosure are: compared to the existing OLED display panel and the fabrication method thereof, the present disclosure, by additionally disposing the inorganic layer more resistant to water and oxygen on a circumferential periphery portion of the organic layer, water and oxygen resistance of the circumferential periphery region of the OLED display panel is increased.

### DESCRIPTION OF DRAWINGS

In order to describe a technical solution in embodiments or existing technology more clearly, drawings required to be used by the embodiments or the existing technology are briefly introduced below. Obviously, the drawings in the description below are only some embodiments of the present disclosure. With respect to persons of ordinary skill in the art, under a premise that inventive efforts are not made, other drawings may be obtained based on these drawings.

FIG. 1 is a schematic structural diagram of an existing OLED display panel.

FIG. 2 is a schematic structural diagram of an OLED display panel in accordance with a first embodiment of the present disclosure.

FIG. 3 is a schematic structural diagram of an OLED display panel in accordance with a second embodiment of the present disclosure.

FIG. 4 is a top view diagram of a structure in the OLED display panel in accordance with the second embodiment of the present disclosure.

FIG. 5 is a schematic structural diagram of an OLED display panel in accordance with a third embodiment of the present disclosure.

FIG. 6 is a schematic flowchart of a method for fabricating the OLED display panel in accordance with a fourth embodiment of the present disclosure.

FIGS. 7a-7e are structural flowcharts of the method for fabricating the OLED display panel in accordance with the fourth embodiment of the present disclosure.

FIG. 8 is a schematic flowchart of a step S30 in the method for fabricating the OLED display panel in accordance with the fourth embodiment of the present disclosure.

FIGS. 9a-9c are specific structural flowcharts of the step S30 in the method for fabricating the OLED display panel in accordance with the fourth embodiment of the present disclosure.

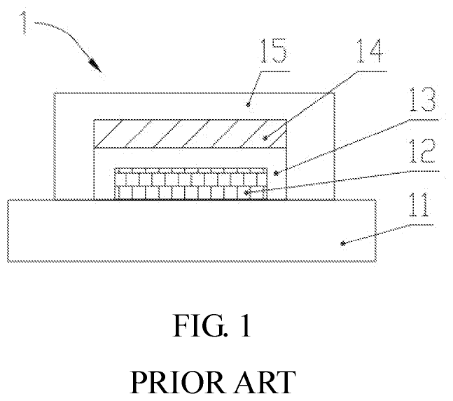

### DETAILED DESCRIPTION OF PREFERRED EMBODIMENTS

The description of each embodiment below refers to respective accompanying drawing(s), so as to illustrate exemplarily specific embodiments of the present disclosure that may be practiced. Directional terms mentioned in the present disclosure, such as “upper”, “lower”, “front”, “back”, “left”, “right”, “inner”, “outer”, “side”, etc., are only directions by referring to the accompanying drawings, and thus the used directional terms are used to describe and understand the present disclosure, but the present disclosure is not limited thereto. In the drawings, structurally similar units are labeled by the same reference numerals.

The present disclosure is directed to the problem that in the existing OLED display panel, a circumferential periphery region is less water and oxygen resistant, causing water and oxygen to invade and an OLED layer to corrode. The present embodiment can solve the deficiency.

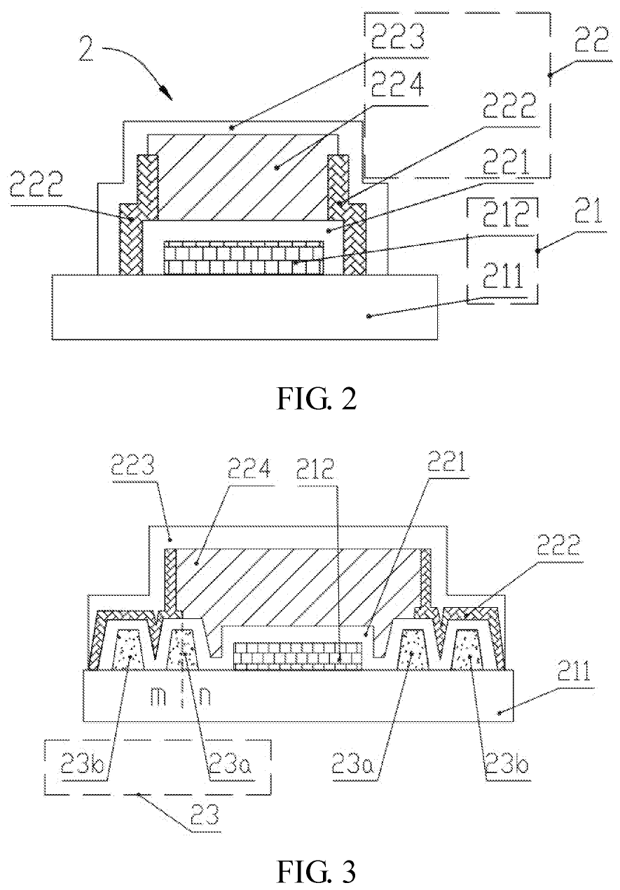

As illustrated in FIG. 2, an OLED display panel 2 is provided. The OLED display panel 2 includes an OLED substrate 21 and a package portion 22 disposed on the OLED substrate 21.

The OLED substrate includes an array substrate 211 and an OLED layer 212 disposed on the array substrate 211.

Specifically, the array substrate 211 includes a substrate and a thin film transistor layer. The thin film transistor layer is disposed on a surface of the substrate. Usually, the array substrate 211 includes a display region, and a non-display region disposed outside the display region. The OLED layer 212 is disposed at the display region.

The OLED layer 212 is composed of an anode, an organic layer, and a cathode. The anode is composed of an indium zinc oxide-silver-indium zinc oxide layer structure which has a high work function and high reflectance. The organic layer includes a hole injection layer, a hole transport layer, a light-emitting layer, an electron transport, and an electron injection layer. The cathode is a magnesium-silver alloy which has a low work function.

Because the organic layer is very sensitive to water and oxygen, it is necessary to dispose the package portion 22 on a surface of the OLED layer 212.

The package portion 22 includes:
a first inorganic layer 221 disposed on the OLED substrate 21 and wrapping the OLED layer 212;
an organic layer 224 disposed on the first inorganic layer 221;
a second inorganic layer 222 covering a circumferential periphery of the first inorganic layer 221; and
a third inorganic layer 223 disposed on the organic layer 224 and covering the organic layer 224 and the second inorganic layer 222.

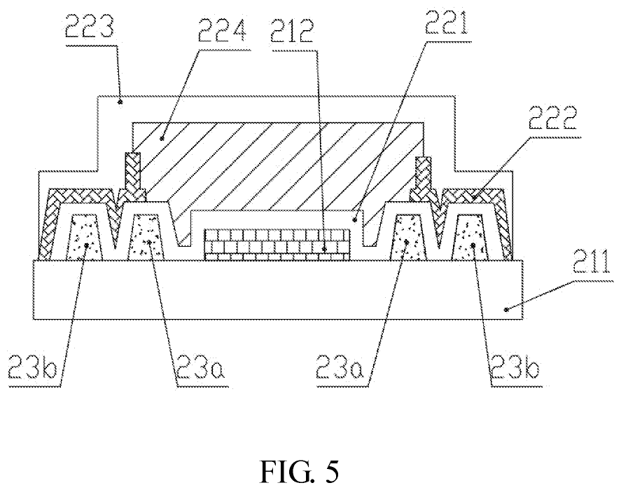

As illustrated in FIG. 5, the second inorganic layer 222 contacts a circumferential periphery of the organic layer 224. That is, the second inorganic layer 222 does not completely cover the circumferential periphery of the organic layer 224. In another embodiment, the second inorganic layer 222 completely covers the circumferential periphery of the organic layer 224, to prevent water and oxygen from entering the OLED layer 212 from the circumferential periphery, causing corrosion.

As illustrated in FIG. 3, the second inorganic layer 222 covers the circumferential periphery of the organic layer 224, to enhance protection effects of the second inorganic layer 222.

Preferably, the second inorganic layer 222 partially covers an upper surface of the organic layer 224. By disposing the second inorganic layer 222 covering a circumferential surface of the organic layer 224 and partially covering the upper surface of the organic layer 224, water and oxygen are prevented from entering the OLED layer 212 from the circumferential surface or the upper surface, water and oxygen resistance of a circumferential surface of the OLED display panel is increased.

As illustrated in FIG. 3, the OLED display panel includes at least one retaining wall 23a. The at least one retaining wall 23a is disposed on the array substrate 211 and surrounding the OLED layer 212. In an embodiment, the first inorganic layer 221 covers all of the at least one retaining wall 23a. The second inorganic layer 222 extends from the at least one retaining wall 23a and a boundary of the second inorganic layer 222 does not exceed a boundary of the first inorganic layer 221.

Preferably, in the OLED display panel 2, there is one retaining wall 23a. The first inorganic layer 221 extends from the OLED layer 212 to a first side m of the retaining wall 23a away from the OLED layer 212, the organic layer 224 is blocked by the retaining wall 23a to be within a second side n of the retaining wall 23a close to the OLED layer, and the second inorganic layer 224 extends from the retaining wall 23a towards an end of the array substrate 211 and completely covers the retaining wall 23a.

Preferably, in the OLED display panel 2, there are at least two retaining walls 23a, the first inorganic layer 221 extends from the OLED layer 212 and covers all of the retaining walls 23a, the second inorganic layer 222 extends from the innermost retaining wall of the retaining walls 23a, and covers the outermost retaining wall of the retaining walls 23a.

The third inorganic layer 223 extends from the OLED layer 212, and a boundary of the third inorganic layer 223 exceeds the boundary of the first inorganic layer 221.

In the present embodiment, by disposing the at least one retaining wall 23a, overflow of the organic layer 222 during a fabrication process is effectively prevented, and a path along which external water and oxygen invades the circumferential surface of the OLED display panel 2 is lengthened.

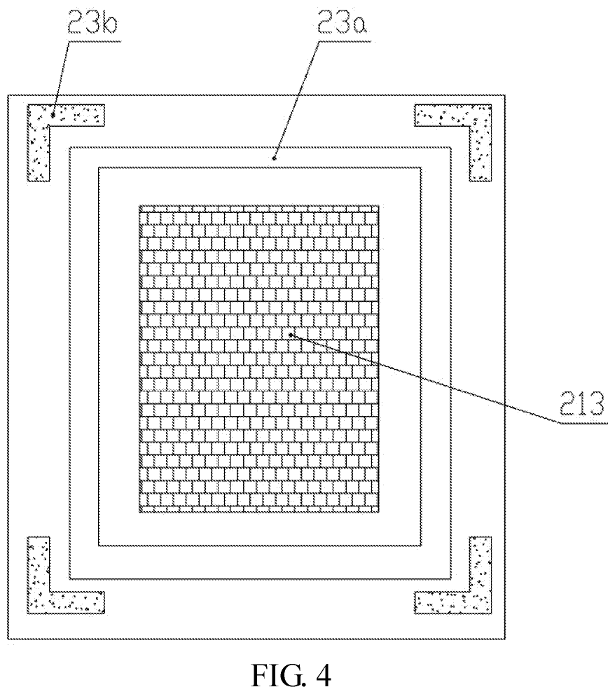

As illustrated in FIGS. 4 and 5, the OLED display panel further includes corner retaining walls 23b disposed at four corners of the array substrate. The corner retaining walls 23b and the at least one retaining wall 23a are disposed in a same layer. The second inorganic layer 222 covers the corner retaining walls 23b.

Preferably, the corner retaining walls 23b are located outside the at least one retaining wall 23a, to save space occupied by the corner retaining walls.

Preferably, the corner retaining walls 23b are located between the retaining walls 273.

Preferably, the at least one retaining wall 23a and the corner retaining walls 273 are separated from each other.

Preferably, the first inorganic layer 221 covers the at least one retaining wall 23a, and the second inorganic layer 222 is disposed over the at least one retaining wall 23a.

In accordance with another aspect of the present disclosure, a method for fabricating an OLED display panel is provided. The method is for preparing any of the OLED display panels of Claims 1-10.

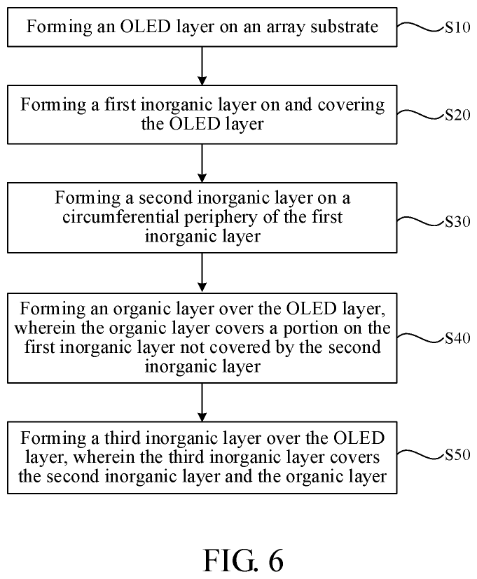

Specifically, as illustrated in FIG. 6, the method for fabricating the OLED display panel includes the following steps.

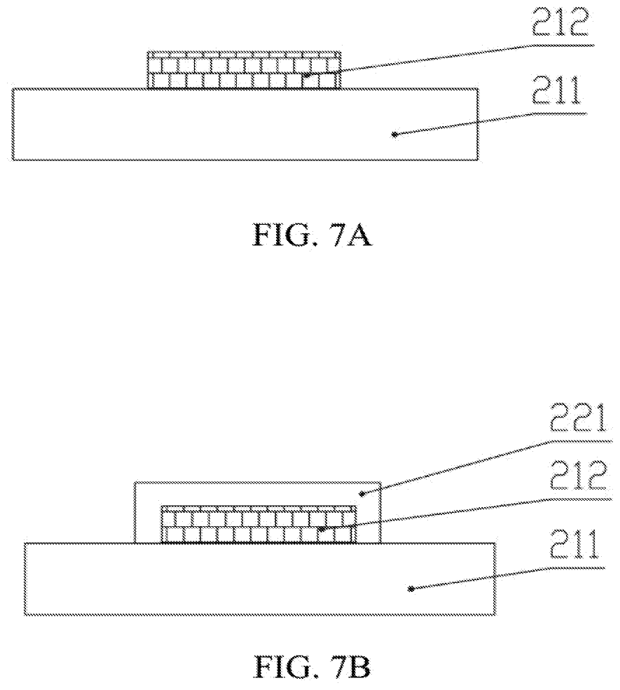

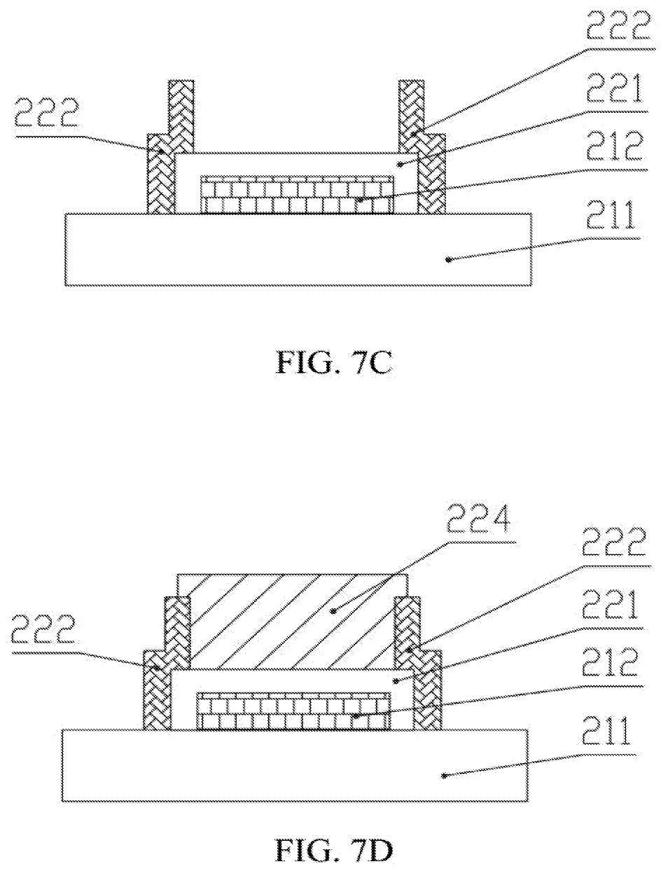

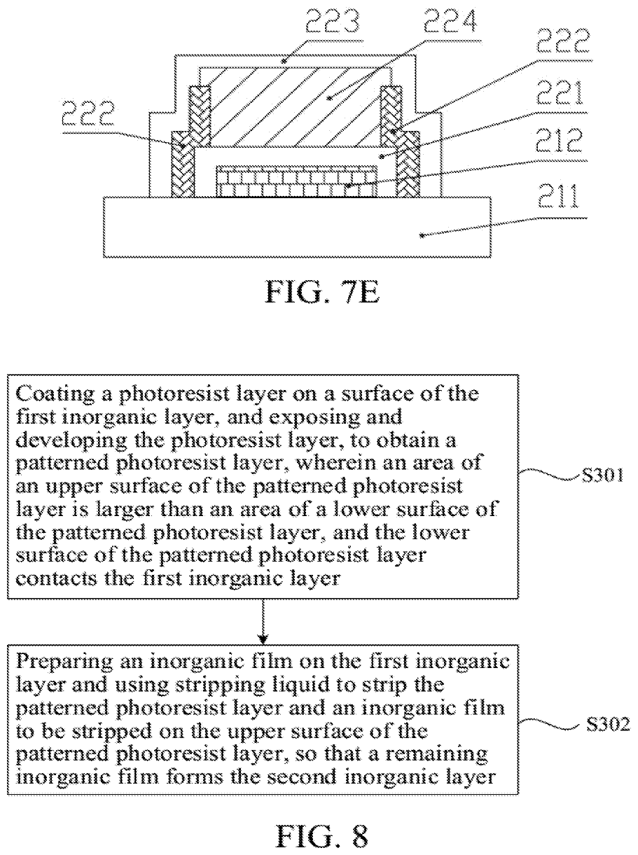

As illustrated in FIG. 7a, in a step S10, an OLED layer 22 is prepared on an array substrate 211. An area of the OLED layer 212 is smaller than an area of the array substrate 211.

Specifically, the array substrate 211 includes a substrate and a thin film transistor layer. The thin film transistor layer is disposed on a surface of the substrate.

The OLED layer 212 is composed of an anode, an organic layer, and a cathode. The anode is composed of an indium zinc oxide-silver-indium zinc oxide layer structure which has a high work function and high reflectance. The organic layer includes a hole injection layer, a hole transport layer, a light-emitting layer, an electron transport, and an electron injection layer. The cathode is a magnesium-silver alloy which has a low work function.

Because the organic layer is very sensitive to water and oxygen, it is necessary to dispose the package portion on a surface of the OLED layer 212.

As illustrated in FIG. 7b, in a step S20, a first inorganic layer 221 is prepared on the surface of the OLED layer 212. The first inorganic layer 221 completely covers the OLED layer 212.

Specifically, two ends of the first inorganic layer 221 are directly connected with the OLED substrate 21. Preparation material of the first inorganic layer 221 is at least one of silicon nitride, silicon dioxide, silicon oxynitride, aluminum oxide, and titanium oxide.

The first inorganic layer 221 is deposited using plasma enhanced chemical vapor deposition.

As illustrated in FIG. 7c, in a step S30, a second inorganic layer 222 is formed on a circumferential periphery region of the first inorganic layer 221. The second inorganic layer 222 is configured to enhance water and oxygen resistance of a circumferential periphery region of the OLED layer 212.

The first inorganic layer 212 is a first package protection of the OLED layer 212.

As illustrated in FIG. 8, the step S30 includes the following steps.

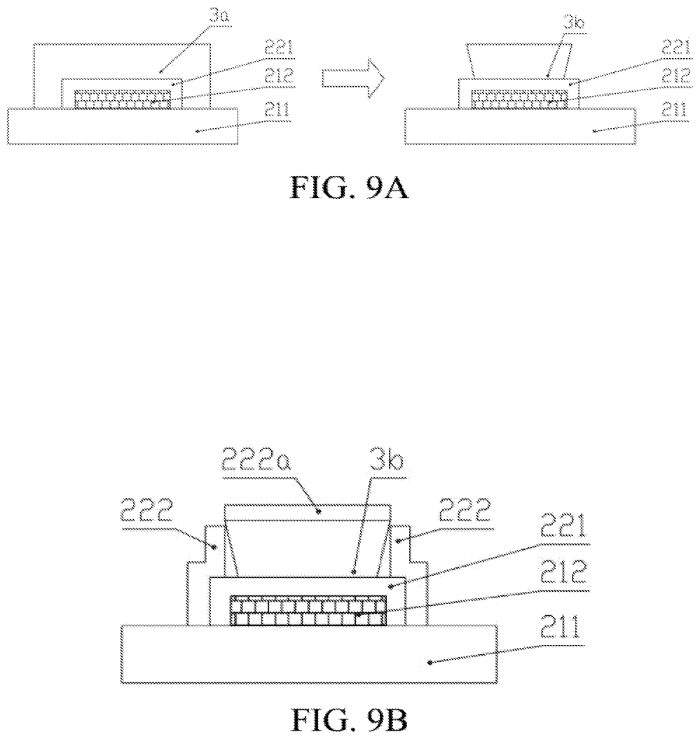

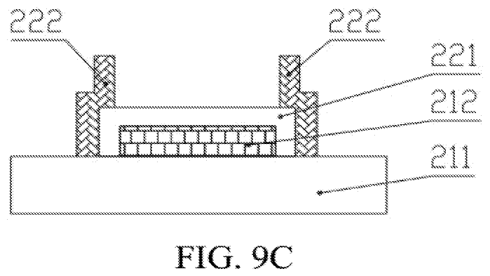

As illustrated in FIG. 9a, in a step S301, a photoresist layer 3a is coated on a surface of the first inorganic layer 221. The photoresist layer 3a is exposed and developed using an exposure machine, to obtain a patterned photoresist layer 3b.

In the present embodiment, because of an overdeveloping process, an area of an upper surface of the patterned photoresist layer 3b is larger than an area of a lower surface of the patterned photoresist layer 3b. The lower surface of the patterned photoresist layer contacts the first inorganic layer 221.

The patterned photoresist layer 3b is located over the OLED layer 212, and an area of the patterned photoresist layer 3b is larger than an area of the OLED layer 212.

The photoresist layer 3a may use a positive photoresist or a revitalizing photoresist. A mask pattern used during exposure depends on whether the positive photoresist or the negative photoresist is used.

As illustrated in FIG. 9b, in a step S302, an inorganic film (222 and 222a) is prepared over the first inorganic layer 221. Because of existence of the patterned photoresist layer 3b, the inorganic film (22 and 222a) is broken at a periphery of the patterned photoresist layer 3b. Because of existence of a broken portion, during a stripping process, the patterned photoresist layer and an inorganic film 222a to be stripped are more easily stripped using stripping liquid, increasing stripping efficiency.

As illustrated in FIG. 9c, in a step S303, the patterned photoresist layer 3b and the inorganic film 222a covering the upper surface of the patterned photoresist layer 3b are stripped using the stripping liquid, to form the second inorganic layer 222.

Specifically, the inorganic film (222 and 222a) is deposited using plasma enhanced chemical vapor deposition.

Preparation material of the inorganic film (222 and 222a) is at least one of silicon nitride, silicon dioxide, silicon oxynitride, aluminum oxide, and titanium oxide.

As illustrated in FIG. 7d, in a step S40, an organic layer 224 is prepared over the OLED layer 212. The organic layer 224 covers a portion of a surface of the first inorganic layer 221 not covered by the second inorganic layer 222. The second inorganic layer 222 and the organic layer 224 completely cover the first inorganic layer 221.

Preparation material of the organic layer 224 is at least one of acrylic, epoxy, and silicon oxide.

The organic layer 25 is prepared using an inkjet printing apparatus.

The second inorganic layer 222 and the organic layer 224 constitute a second package protection of the OLED layer 212. Because of existence of the second inorganic layer 222, water and oxygen resistance of a circumferential periphery region of the OLED display panel 2 is effectively increased.

As illustrated in FIG. 7e, in a step S50, a third inorganic layer 223 is prepared over the OLED layer 212. The third inorganic layer 223 completely covers the second inorganic layer 222 and the organic layer 224.

Preparation material of the third inorganic layer 223 is at least one of silicon nitride, silicon dioxide, silicon oxynitride, aluminum oxide, and titanium oxide. The third inorganic layer is prepared using plasma enhanced chemical vapor deposition.

Inorganic thin films may have excellent water and oxygen barrier properties. Organic thin films may absorb and disperse stress between layers well, avoiding cracks lowering water and oxygen barrier properties to be formed. In the present embodiment, by replacing an organic layer forming a circumferential periphery portion with the inorganic layer for the OLED layer, water and oxygen resistance of a circumferential periphery portion of the OLED display panel is effectively increased.

In the present embodiment, each end of the first inorganic layer 221, the second inorganic layer 222, and the third inorganic layer 223 directly contacts the OLED substrate 21.

Operating principles of the OLED display panel in accordance with the preferred embodiments are same as operating principles of the method for fabricating the OLED display panel in accordance with the above preferred embodiments. Details of the operating principles of the method for fabricating the OLED display panel have been provided above, and are omitted here.

Advantages of the present disclosure are: compared to the existing OLED display panel, the present disclosure, by covering a circumferential periphery portion of the organic layer of an external package of the OLED display panel with the inorganic layer more resistant to water and oxygen, water and oxygen resistance of the circumferential periphery region of the OLED display panel is increased, and product quality of the OLED display panel is enhanced.

In summary, although the present disclosure has been described with preferred embodiments thereof above, it is not intended to be limited by the foregoing preferred embodiments. Persons skilled in the art can carry out many changes and modifications to the described embodiments without departing from the scope and the spirit of the present disclosure. Therefore, the protection scope of the present disclosure is in accordance with the scope defined by the claims.

What is claimed is:

1. An organic light-emitting diode (OLED) display panel, comprising an OLED substrate and a package portion disposed on the OLED substrate;
wherein the OLED substrate comprises an array substrate and an OLED layer disposed on the array substrate;
wherein the package portion comprises:
a first inorganic layer disposed on the OLED substrate and covering the OLED layer;
an organic layer disposed on the first inorganic layer;
a second inorganic layer disposed on a circumferential periphery of the first inorganic layer, wherein the second inorganic layer partially covers an upper surface of the organic layer; and
a third inorganic layer disposed on the organic layer and covering the organic layer and the second inorganic layer.

2. The OLED display panel of claim 1, wherein the second inorganic layer contacts a circumferential periphery of the organic layer.

3. The OLED display panel of claim 1, wherein the second inorganic layer covers a circumferential periphery of the organic layer.

4. The OLED display panel of claim 1, further comprising: at least one retaining wall disposed on the array substrate and surrounding the OLED layer.

5. The OLED display panel of claim 4, wherein the first inorganic layer covers the at least one retaining wall, and the second inorganic layer extends from the at least one retaining wall and a boundary of the second inorganic layer does not exceed a boundary of the first inorganic layer.

6. The OLED display panel of claim 4, wherein there is one retaining wall, the first inorganic layer extends from the OLED layer to a first side of the retaining wall away from the OLED layer, the organic layer is blocked by the retaining wall to be within a second side of the retaining wall close to the OLED layer, and the second inorganic layer extends from the retaining wall towards an end of the array substrate and completely covers the retaining wall.

7. The OLED display panel of claim 5, wherein there are at least two retaining walls, the first inorganic layer extends from the OLED layer and covers all of the retaining walls, the second inorganic layer extends from the innermost retaining wall of the retaining walls, and covers the outermost retaining wall of the retaining walls.

8. The OLED display panel of claim 5, wherein the third inorganic layer extends from the OLED layer, and a boundary of the third inorganic layer exceeds the boundary of the first inorganic layer.

9. A method for fabricating an organic light-emitting diode (OLED) display panel, comprising:
a step S10 of forming an OLED layer on an array substrate;
a step S20 of forming a first inorganic layer on and covering the OLED layer;
a step S30 of forming a second inorganic layer on a circumferential periphery of the first inorganic layer;
a step S40 of forming an organic layer over the OLED layer, wherein the organic layer covers a region of the first inorganic layer not covered by the second inorganic layer; and
a step S50 of forming a third inorganic layer over the OLED layer, wherein the third inorganic layer covers the second inorganic layer and the organic layer.

10. The method for fabricating the OLED display panel of claim 9, wherein the step S30 comprises:
a step S301 of coating a photoresist layer on a surface of the first inorganic layer, and exposing and developing the photoresist layer, to obtain a patterned photoresist layer, wherein an area of an upper surface of the patterned photoresist layer is larger than an area of a lower surface of the patterned photoresist layer, and the lower surface of the patterned photoresist layer contacts the first inorganic layer; and
a step S302 of preparing an inorganic film over the first inorganic layer and using stripping liquid to strip the patterned photoresist layer and an inorganic film to be stripped on the upper surface of the patterned photoresist layer, so that a remaining inorganic film forms the second inorganic layer.

11. The method for fabricating the OLED display panel of claim 10, wherein the patterned photoresist layer is located over the OLED layer, and an area of the patterned photoresist layer is larger than an area of the OLED layer.

12. An organic light-emitting diode (OLED) display panel, comprising an OLED substrate and a package portion disposed on the OLED substrate;
wherein the OLED substrate comprises an array substrate and an OLED layer disposed on the array substrate;
wherein the package portion comprises:
a first inorganic layer disposed on the OLED substrate and covering the OLED layer;
an organic layer disposed on the first inorganic layer;
a second inorganic layer disposed on a circumferential periphery of the first inorganic layer; and
a third inorganic layer disposed on the organic layer and covering the organic layer and the second inorganic layer.

13. The OLED display panel of claim 12, wherein the second inorganic layer contacts a circumferential periphery of the organic layer.

14. The OLED display panel of claim 12, wherein the second inorganic layer covers a circumferential periphery of the organic layer.

15. The OLED display panel of claim 12, further comprising: at least one retaining wall disposed on the array substrate and surrounding the OLED layer.

16. The OLED display panel of claim 15, wherein the first inorganic layer covers the at least one retaining wall, and the second inorganic layer extends from the at least one retaining wall and a boundary of the second inorganic layer does not exceed a boundary of the first inorganic layer.

17. The OLED display panel of claim 15, wherein there is one retaining wall, the first inorganic layer extends from the OLED layer to a first side of the retaining wall away from the OLED layer, the organic layer is blocked by the retaining wall to be within a second side of the retaining wall close to the OLED layer, and the second inorganic layer extends from the retaining wall towards an end of the array substrate and completely covers the retaining wall.

18. The OLED display panel of claim 16, wherein there are at least two retaining walls, the first inorganic layer extends from the OLED layer and covers all of the retaining walls, the second inorganic layer extends from the innermost retaining wall of the retaining walls, and covers the outermost retaining wall of the retaining walls.

19. The OLED display panel of claim 16, wherein the third inorganic layer extends from the OLED layer, and a boundary of the third inorganic layer exceeds the boundary of the first inorganic layer.
